(19) United States
(12) Patent Application Publication
(10) Pub. No.: US 2012/0065911 A1
(43) Pub. Date: Mar. 15, 2012

(54) METHOD AND APPARATUS FOR SPECTRUM SENSING OF FM WIRELESS MICROPHONE SIGNALS

(76) Inventors: Hou-Shin Chen, East Brunswick, NJ (US); Wen Gao, West Windsor, NJ (US)

(21) Appl. No.: 13/321,052

(22) PCT Filed: May 18, 2010
(86) PCT No.: PCT/US10/01467

§ 371 Date: Nov. 17, 2011

Related U.S. Application Data
(60) Provisional application No. 61/280,336, filed on Nov. 2, 2009.
(60) Provisional application No. 61/216,872, filed on May 22, 2009.

(51) Int. Cl. G01R 23/16; G06F 19/00

(52) U.S. Cl. 702/76

(57) ABSTRACT

Methods and apparatus for spectrum sensing for FM wireless microphone signals are provided. The spectrum sensing algorithm developed makes use of the property that the autocorrelation function of an FM signal is a sinusoidal function provided that the frequency) deviation is much smaller than the carrier frequency and the correlation delay is small. Based on this property, a simple spectrum sensing algorithm for the FM signal is designed by computing the autocorrelation function of the received signal and matched filtering of the sinusoidal function. The spectrum sensor provided by this approach can reliably detect the target signals when a strong adjacent channel interference exists and the signal power is as low as −114 dBm.

### CROSS-REFERENCE TO RELATED APPLICATIONS

This application claims the benefit of U.S. Provisional Application Ser. No. 61/216872, entitled “SPECTRUM SENSING FOR TV WHITE SPACE IN NORTH AMERICA,” filed May 22, 2009 and U.S. Provisional Application Ser. No. 61/280,336, entitled “SPECTRUM SENSING FOR FM WIRELESS MICROPHONE SIGNALS,” filed Nov. 2, 2009, which are incorporated by reference herein in their entirety.

### FIELD OF THE INVENTION

The present principles relate to spectrum sensing of FM wireless microphone signals and systems.

### BACKGROUND OF THE INVENTION

Cognitive Radio was proposed to implement negotiated, or opportunistic, spectrum sharing to improve spectrum efficiency. Recently, the Federal Communications Commission (FCC) has approved operation of unlicensed radio transmitters in the broadcast television spectrum at frequencies which are unused by licensed services (this unused TV spectrum is often termed “white space”) under certain rules. A major regulation is that the white space devices will be required to sense, at levels as low as −114 dBm, TV signals (digital and analog), wireless microphone (WM) signals, and signals of other services that operate in the TV bands on intermittent basis. Hence spectrum sensing is an important enabling technique for the deployment of cognitive radios in TV white space. Note that the noise power in a 6 MHz TV channel under normal temperature is about −96 dBm assuming that the noise figure of a sensing device is 10 dB. Thus, the sensing requirement set by FCC is about −18 dB in terms of signal-to-noise power ratio (SNR) resulting in a rather difficult task.

Spectrum sensing of FM wireless microphone signals under strong interference is a very challenging task. To address this problem, a simple spectrum sensing method is developed herein that utilizes an important property of an FM signal, i.e., its autocorrelation function can be approximated as a sinusoidal function provided that the frequency deviation is much smaller than its carrier frequency and the correlation delay is small. Computer simulations demonstrate that this proposed spectrum sensor can reliably detect the target signals when a strong adjacent channel interference exists and the signal power is as low as −114 dBm, as set by the Federal Communications Commission (FCC) in their reports on so-called white space device.

A uniform framework of spectrum sensing of ATSC/NTSC signals has been proposed in a companion application (PCT/US10/000961). The principles described herein will focus on sensing of wireless microphone signals. In the United States, wireless microphones are low-power secondary licensed signals in TV bands and are regulated by FCC Radio Broadcast Rules in Title 47 Codes of Federal Regulations (CFR), Part 74 (47 CFR 74). There are four main regulations for wireless microphone usage: (1) The wireless microphones are allowed to operate in unused VHF or UHF TV bands listed in 47 CFR 74. (2) The frequency selection shall be offset from the upper or lower band limits by 25 kHz or an integral multiple thereof. (3) One or more adjacent 25 kHz segments within the assignable frequencies may be combined to form a channel whose maximum bandwidth shall not exceed 200 kHz. (4) The maximum transmitter power is 50 mW in VHF bands and 250 mW in UHF bands. In other countries, wireless microphone operations are regulated by different agencies, but with technical characteristics generally similar to those in the United States. The majority of the wireless microphone devices use analog Frequency Modulation (FM) although other types of modulations such as digital or hybrid analog/digital modulations are also used in a variety of FM devices on the market. Blind spectrum sensing methods, e.g., Eigenvalue-Based algorithms, can be applied to sense a wireless microphone signal regardless of its modulation type. Another method is to look for a spectrum peak in the frequency domain. The bandwidth of wireless microphone signals is less than 200 kHz, much smaller than that of a TV band (6 MHz). As a result, the power of wireless microphone signals is very concentrated while the noise power is uniformly distributed over the whole 6 MHz band. Thus, a spectrum peak usually appears in the spectrum of wireless microphone signals. However, both methods produce high false alarm rates when a strong adjacent channel interference is present. The problem of sensing wireless microphone signals with the presence of adjacent channel interference is very difficult. The center frequency of a wireless microphone signal may be only 50 kHz from the adjacent channel edge in the FCC's Adjacent Channel Interference test model. Signals around this frequency band are severely affected by the interference leaked from TV signals in the lower adjacent channels. Thus, the wireless microphone signal may be fully shaded by the adjacent channel interference.

In this invention, a spectrum sensing method for wireless microphone signals using FM modulation is described. The proposed method can determine the presence of FM-based wireless microphone signals even with strong adjacent channel interference. The spectrum sensing method is described below, followed by the sensing threshold setting with corresponding probability of false alarm (P_{FA}). The sensing performances of the proposed spectrum sensor is evaluated by computer simulations and also described, followed by a conclusion.

### SUMMARY OF THE INVENTION

These and other drawbacks and disadvantages of the prior art are addressed by the present principles, which are directed to a method and apparatus for spectrum sensing of FM-based wireless microphone signals.

According to an aspect of the present principles, there is provided a method for spectrum sensing. The method includes the steps of generating an autocorrelation function on a received signal, filtering the output of the autocorrelation function with a matched filter, generating a decision statistic by finding a maximum value of the matched filter output, and using the decision statistic to determine occupied spectrum space.

According to another aspect of the present principles, there is provided an apparatus for spectrum sensing. The apparatus includes a processing circuit for generating an autocorrelation function on a received signal, a matched filter for filtering the autocorrelation output, a decision circuit for generating a decision statistic by finding the maximum value of the matched filter output, and a detection unit for using said decision statistic to determine occupied spectrum space.

According to another aspect of the present principles, there is provided another method of performing spectrum sensing. The method includes the steps of generating an autocorrelation function on a received signal, computing a higher order statistic using the autocorrelation output, generating a decision statistic by finding the maximum value of said higher order statistic, and using said decision statistic to determine occupied spectrum space.

According to another aspect of the present principles, there is provided another apparatus. The apparatus includes a processing circuit for generating an autocorrelation function on a received signal, a computing circuit for calculating a higher order statistic using the autocorrelation output, a decision circuit for generating a decision statistic by finding the maximum value of the matched filter output, and a detection unit for using said decision statistic to determine occupied spectrum space.

These and other aspects, features and advantages of the present principles will become apparent from the following detailed description of exemplary embodiments, which is to be read in connection with the accompanying drawings.

### BRIEF DESCRIPTION OF THE DRAWINGS

FIG. 1 shows a simulation model of wireless microphone signals.

FIG. 2 shows the sensing performance of wireless microphone signals without interference and sensing time of 5 ms.

FIG. 3 shows a family of Receiver Operating Characteristic (ROC) curves for wireless microphone signals without interference at different levels of SNR and sensing time of 5 ms.

FIG. 4 shows the sensing performance of wireless microphone signals with interference and sensing time of 100 ms.

FIG. 5 shows a family of ROC curves for wireless microphone signals with interference at different levels of SNR and sensing time of 100 ms.

FIG. 6 shows the steps of a first exemplary method illustrating the principles of the present invention.

FIG. 7 shows a first exemplary apparatus illustrating the principles of the present invention.

FIG. 8 shows the steps of a second exemplary method illustrating the principles of the present invention.

FIG. 9 shows a second exemplary apparatus illustrating the principles of the present invention.

### DETAILED DESCRIPTION

An approach for spectrum sensing of FM wireless microphone signals is described herein.

### Autocorrelation Function of FM Signals

Frequency modulation is an analog modulation scheme. The frequency of the sinusoidal carrier wave is varied in accordance with the baseband signal. The FM signal x(t) can be described by

x(t)=A_{c} cos[2πf_{c}t+2πΔf ∫′₀m(u)du+θ] (1)

where θ is a random phase uniformly distributed on (0,2π) and m(t) is a transmitted voice signal. It is zero-mean and its amplitude is |m(t)|≦1. The parameters A_{c} and f_{c} are carrier amplitude and carrier frequency, respectively. The constant Δf is the frequency deviation of an FM modulator, representing the maximum departure of the instantaneous frequency of the FM signal from the carrier frequency f_{c}. In addition, it can be shown that the autocorrelation function of the FM signal, x(t) is given by

$$\begin{matrix}{R}_{x} ( τ ) = E [ x ( t + τ ) x ( t ) ] \\ = \frac{{A}_{c}^{2}}{2} E [ cos ( 2 π {f}_{c} τ + 2 π Δ f {\int }_{t}^{t + τ} m ( u ) d u ) ]\end{matrix} \qquad ( 2 )$$

where the first expectation is over θ and m(t) while the second expectation is over m(t). The integral term inside the cosine function has a maximum value of 2πΔfτ. Several prior wireless microphone simulation models use a suggested maximum frequency deviation of 32.6 kHz. The carrier frequency f_{c} is in the order of MHz. For example, let's have f_{c}=3.26 MHz which is 100 times of the maximum value of Δf. For a period of 0≦τ≦10 μs, the phase variation caused by the carrier frequency is 65.2π (32.6 cycles) while only a maximum of about 0.6π is contributed by the integral term at τ=10 μs. Therefore, when f_{c}>>Δf and the correlation delay τ is small, the phase variation is dominated by the carrier frequency and the contribution of the integral term can be ignored. Based on the observations above, we have

$${R}_{x} ( τ ) ; \frac{{A}_{c}^{2}}{2} cos ( 2 π {f}_{c} τ ) \qquad ( 3 )$$

given that f_{c}>×Δf and τ is small.
Spectrum Sensing Algorithms without Interference

Assume that the received analog signal is r(t),

r(t)=x(t)+w(t) (4)

where w(t) is an additive white Gaussian noise (AWGN). The analog signal r(t) is sampled at a sampling frequency of fₛ by an Analog-to-Digital Converter (ADC), i.e., r[n]=r(n/fₛ). The autocorrelation function is computed by

$${R}_{r} [ m ] = \frac{1}{{N}_{r}} {\sum }_{n = 0}^{{N}_{r} - 1} r [ n + m ] \cdot r [ n ] \qquad ( 5 )$$

where Nᵣ is the number of samples used to compute Rᵣ[m]. Note that the estimated autocorrelation function given in (5) is computed by averaging over the same number of lag products. That means not all available signal samples are utilized to compute an estimated autocorrelation function. By doing so, the sample autocorrelation function, Rᵣ[m] will have the same variance for different correlation delay m. The formulation of the threshold setting will also be simplified. Note that the accuracy of the estimated autocorrelation function is not affected because Nᵣ is much larger than the largest correlation delay. Since the FM signal x(t) and noise w(t) are both zero-mean and they are independent, the autocorrelation function of the received signal r[n] consists of the sum of the autocorrelation functions of these two signals,

$${R}_{r} [ m ] = {R}_{x} [ m ] + {R}_{w} [ m ] ; \\ \frac{{A}_{c}^{2}}{2} cos ( 2 π {f}_{c} m / {f}_{s} ) + {R}_{w} [ m ] . \qquad ( 6 )$$

Note that, ideally, the auto correlation function of the noise, R_{w}[m], is zero for m ≠ 0. In practice, although the values of R_{w}[m]are not zero for m ≠ 0, it is relatively small compared to the value of R_{w}[0]. If the carrier frequency of the FM signal is known, the optimal detector is a matched filter, i.e., the decision statistic of the optimal detector is given by

$${T}_{R} ( {f}_{c} ) = \frac{1}{M} {\sum }_{m = 1}^{M} {R}_{r} [ m ] \cdot cos ( 2 π {f}_{c} m / {f}_{s} ) . \qquad ( 7 )$$

where M is the number of Rᵣ[m] values computed for different m. However, the carrier frequency of a wireless microphone device can be any frequency within a TV channel as long as the carrier frequency offsets from TV channel edge is a multiple of 25 kHz. Assume that the received signal occupies a band from P MHz to (P+6) MHz. The wireless microphone devices can select f₀=P MHz+50 kHz, f₁=P MHz+75 kHz, . . . , f_{N}_{_{f}}₋₁=(P+6) MHz-50 kHz, as its carrier frequency. There are totally N_{f}=1+(6 MHz-100 kHz)/(25 kHz)=237 possible carrier frequencies. As a result, the decision statistic of the optimal FM signal sensor is given by

$${T}_{R} = {max}_{0 \leq n \leq {N}_{f} - 1} {T}_{R} ( {f}_{n} ) . \qquad ( 8 )$$

Spectrum Sensing Algorithms with Interference

When the received analog signal, r(t) contains an interference signal, we have

r(t)=x(t)+i(t)+w(t) (9)

where i(t) is interference signal. Because the FM signal x(t), interference signal i(t), and noise w(t) are zero-mean and they are mutually independent, the autocorrelation function of the received signal r[n] consists of the sum of the autocorrelation functions of these three signals,

$${R}_{r} [ m ] = {R}_{x} [ m ] + {R}_{i} [ m ] + {R}_{w} [ m ] ; \\ \frac{{A}_{c}^{2}}{2} cos ( 2 π {f}_{c} m / {f}_{s} ) + {R}_{i} [ m ] + {R}_{w} [ m ] . \qquad ( 10 )$$

An observation is that the autocorrelation function of the interference signal, Rᵢ[m], has significantly large values when the correlation delay m is small. Another observation is that like most signals, Rᵢ[n] diminishes when the correlation delay m increases. The sinusoidal property of Rᵢ[m] is destroyed by Rᵢ[m] when the correlation delay m is small. However, for sufficiently large m, say m≧D, Rᵣ[m] will reveal the sinusoidal property of the FM signal. Note that D depends on the statistic property of the adjacent channel interference and it is determined heuristically. Thus, we shall use the values of sample autocorrelation function which reflect the sinusoidal property of FM signals to form the decision statistic of an FM signal spectrum sensing device, i.e.,

$${T}_{R} ( {f}_{c} ) = \frac{1}{M} {\sum }_{m = D}^{M + D - 1} {R}_{r} [ m ] \cdot cos ( 2 π {f}_{c} m / {f}_{s} ) . \qquad ( 11 )$$

for a known carrier frequency f_{c}. However, recall that the approximation made in (3) is correct for small values of correlation delay. It is possible that the value of D is very large so that the approximation made in (3) is invalid. In this situation, the spectrum sensing algorithm given in (11) only works for small frequency deviations. To solve this problem, let's consider a higher order statistic given by

$${Z}_{x} ( λ ) = \frac{1}{T} {\int }_{τ = {T}_{D}}^{{T}_{D} + T} {R}_{x} ( τ + λ ) {R}_{x} ( τ ) d τ . \qquad ( 12 )$$

The integration starts from T_{D} and the result is not affected by T_{D} as long as the integration time, T is large enough. The function, Z(λ), consists of two terms as shown.

$${Z}_{x} ( λ ) = \frac{{A}_{c}^{4}}{4} \frac{1}{T} {\int }_{τ = {T}_{D}}^{{T}_{D} + T} cos ( 2 π {f}_{c} λ + 2 π Δ f {\int }_{t + τ}^{t + τ + λ} m ( u ) d u ) d τ + \frac{{A}_{c}^{4}}{4} \frac{1}{T} {\int }_{τ = {T}_{D}}^{{T}_{D} + T} cos ( 4 π {f}_{c} τ + 2 π {f}_{c} λ + 2 π Δ f {\int }_{t}^{t + r} m ( u ) d u + 2 πΔ f {\int }_{t}^{t + τ + λ} m ( u ) d u ) d τ \qquad ( 13 )$$

When T is getting large, the second term approaches zero. As a result,

$${Z}_{x} ( λ ) ; \frac{{A}_{c}^{4}}{4} cos ( 2 π {f}_{c} λ ) \qquad ( 14 )$$

given that f_{c}>>Δf and λ is small for the same reason in obtaining (3). Note that the function Z(λ) is only related to the time difference of the correlation of R(τ) defined in (12). Thus, we can use R(τ) with large values of τ to compute Z(λ).

The higher order statistic is computed by

$$\begin{matrix}{Z}_{r} [ k ] = \frac{1}{M - k} {\sum }_{n = D}^{D + M - k - 1} {R}_{r} [ n + k ] {R}_{r} [ n ] \\ and & ( 15 ) \\ {Z}_{r} [ k ] ; \frac{{A}_{c}^{4}}{4} cos ( 2 π {f}_{c} k / {f}_{s} ) + {Z}_{i} [ k ] + {Z}_{w} [ k ] . & ( 16 )\end{matrix}$$

The decision statistic of the optimal FM detector is then given by

$$\begin{matrix}{T}_{z} = {max}_{0 \leq n \leq {N}_{f} - 1} {T}_{Z} ( {f}_{n} ) \\ where & ( 17 ) \\ {T}_{Z} ( {f}_{n} ) = \frac{1}{K} {\sum }_{k = 1}^{K} {Z}_{r} [ k ] \cdot cos ( 2 π {f}_{n} k / {f}_{s} ) . & ( 18 )\end{matrix}$$

### Threshold Setting for a Specific Probability of False Alarm

Consider that there is only AWGN noise present and the autocorrelation-based spectrum sensor specified in (8) is used to perform spectrum sensing. By substituting r[n] with w[n] in (5), we have

$${R}_{w} [ m ] = \frac{1}{{N}_{r}} {\sum }_{n = 0}^{{N}_{r} - 1} w [ n + m ] \cdot w [ n ] \qquad ( 19 )$$

Assume that the noise variance is E(w²[n])=σ² and from the Central Limit Theorem, when Nᵣ is sufficiently large, R_{w}[m] is approaching to a zero-mean Gaussian random variable with a variance of

$$\frac{{σ}^{4}}{{N}_{r}} .$$

In addition, {R_{w}[m]}_{m=D}^{M+D}^{D-1} are independently and identically distributed (i.i.d.) Gaussian Random variables. Since the addition of Gaussian random variables is still Gaussian, the random variables {T_{R}(fₙ)}ₙ₌₀^{N}^{_{f}}⁻¹ are identical zero-mean Gaussian random variables with a variance of

$${σ}_{{T}_{R}}^{2} = \frac{{σ}^{4}}{2 {MN}_{r}} .$$

Consider the correlation of two sequences of {cos(2πfₙm/fₛ)}ₙ₌₀^{N}^{_{f}}⁻¹,

$${R}_{c} ( {f}_{n} , {f}_{k} ) = \frac{1}{M} {\sum }_{m = 1}^{M} cos ( 2 π {f}_{n} m / {f}_{s} ) \cdot cos ( 2 π {f}_{k} m / {f}_{s} ) . \qquad ( 20 )$$

When the length of the sequences, M is large enough, we have

$${R}_{c} ( {f}_{n} , {f}_{k} ) = \{ \begin{matrix}\frac{1}{2} & {f}_{n} = {f}_{k} \\ 0 & {f}_{n} \neq {f}_{k}\end{matrix} \qquad ( 21 )$$

Thus, {cos(2πfₙm/fₛ)}ₙ₌₀^{N}^{_{f}}⁻¹ are orthogonal sequences when the length of the sequences is large enough. Hence, (T_{R}(fₙ)}ₙ₌₀^{N}^{_{f}}⁻¹ are i.i.d. Gaussian random variables. Consequently, the cumulative distribution function of the decision statistic is given by

$${F}_{{T}_{R}} ( x \text{:} {H}_{0} ) = {( {\int }_{- ∞}^{x} \frac{1}{\sqrt{2 π} {σ}_{{T}_{R}}} {e}^{- \frac{{u}^{2}}{2 {σ}_{{T}_{R}}^{2}}} d u )}^{{N}_{f}} . \qquad ( 22 )$$

Then, for a particular P_{FA}, the corresponding threshold γ_{T}_{_{R}} can be found by

P_{FA}=1−F_{T}(γ_{T}_{_{R}}:H₀). (23)

Finally, after some straightforward calculation, we have

γ_{T}_{_{R}}=σ_{T}_{_{R}}·Q⁻¹(1−(1−P_{FA})^{1/N}^{_{f}}) (24)

where Q⁻¹(•) is the inverse function of the function

$$Q ( x ) = {\int }_{x}^{∞} \frac{1}{\sqrt{2 π}} {e}^{- \frac{1}{2} {u}^{2}} d u . \qquad ( 25 )$$

When the adjacent channel interference is taken into consideration, the higher-order-statistic-based spectrum sensor specified in (18) is used to perform spectrum sensing. Because the statistic of the interference signal is unknown, the threshold can only be determined by a heuristic method. For example, we can run 10000 simulations and record the resulting statistics. For P_{FA}=0.5%, the 51^{th} statistic of the 10000 statistics sorted in decreasing order is the required threshold.

### Simulation Results

Prior approaches have suggested three wireless microphone operating situations and two environment conditions to test spectrum sensing algorithms for wireless microphone signals. The three system operating situations are:

1. Silent Mode:

The system user is silent. In this situation, m(t) is a 32 kHz sinusoid signal and the FM deviation factor is ±5 kHz.

2. Soft Speaker Mode:

The system user is a soft speaker. In this situation, m(t) is modeled as a 3.9 kHz sinusoid signal with the FM deviation factor being ±15 kHz.

3. Loud Speaker Mode:

The system user is a loud speaker. In this situation, m(t) is modeled as a 13.4 kHz sinusoid signal with the FM deviation factor being ±32.6 kHz.

The two environmental conditions are:

1. Outdoor, LOS:

In this case, the wireless microphone system is used in an outdoor environment where a line of sight (LOS) transmission path between transmitter and receiver exists. Therefore, it is an AWGN channel model.

2. Indoor, Rayleigh Faded:

In this case, the wireless microphone system is used in an indoor environment. Because the distance between transmitter and receiver is short, a single-path Rayleigh fading channel is good enough to model the indoor channel. Therefore, a flat fading channel is used. Moreover, the speed of the user is assumed to be 0.6 m/s. At this speed and at the maximum carrier frequency of 806 MHz, the maximum Doppler shift is computed to be 1.612 Hz. Because the maximum Doppler shift is very small, the Doppler effect can be ignored. Hence, this channel is a single-path time-invariant channel.

Furthermore, a more accurate model of voice signals is used in some prior art methods. The audio signal m(t) is modelled as colored noise that is generated by passing white noise through the circuit followed by pre-emphasis filter prior to FM modulation. Here, the three operating situations in an indoor environment, as well as the colored noise voice model with Δf=32.6 kHz, are used to generate FM wireless microphone signals in simulations.

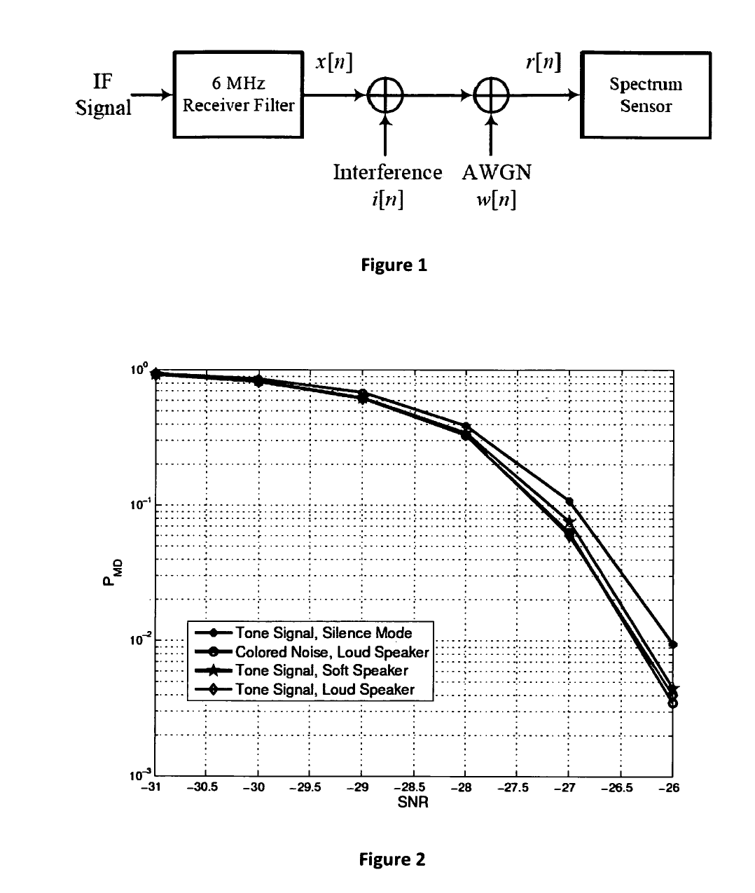

FIG. 1 illustrates the simulation model for the wireless microphone signals. The wireless microphone signals, which are converted to a lower center Intermediate Frequency (f_{IF}), are sampled at a rate of fₛ to generate discrete signals x[n]. If the adjacent channel interference is considered, according to the Two-Signal (Adjacent Channel Interference) model, an interference signal from the lower TV channel is added. The signal power of the lower adjacent channel is −28 dBm and the total out-of-band emission (interference) power is −90 dBm. The additive white Gaussian noise (AWGN) w[n] is added to form the experimental received signal r[n]. We will further assume that w[n] is zero-mean and the noise power spectral density (PSD) is N₀=−174+10=−164 dBm/Hz where −174 dBm/Hz is thermal noise power spectral density under normal temperature conditions and 10 is the noise figure of the receiver. Therefore, the noise power is N₀B=−164 dBm/Hz·6 MHz=−96 dBm. Note that the interference signal power is −90 dBm and the noise power is about −96 dBm. The interference-plus-noise power is −89 dBm. Thus, the sensitivity of −114 dBm set by FCC is equivalently −25 dB in terms of signal to interference-plus-noise power ratio (SINR) which is an extremely difficult condition. It is possible that wireless microphone signals are fully masked by interference signals when the carrier frequency is close to the channel edge. This makes spectrum sensing of wireless microphone signals a very difficult task. In the described simulations, the same setting of f_{IF}=5.38 MHz and fₛ=21.52 MHz in are used. The carrier frequency of FM wireless microphone signals is randomly selected from N_{f}=237 possible carrier frequencies in a 6 MHz band from 2.38 MHz to 8.38 MHz as mentioned earlier.

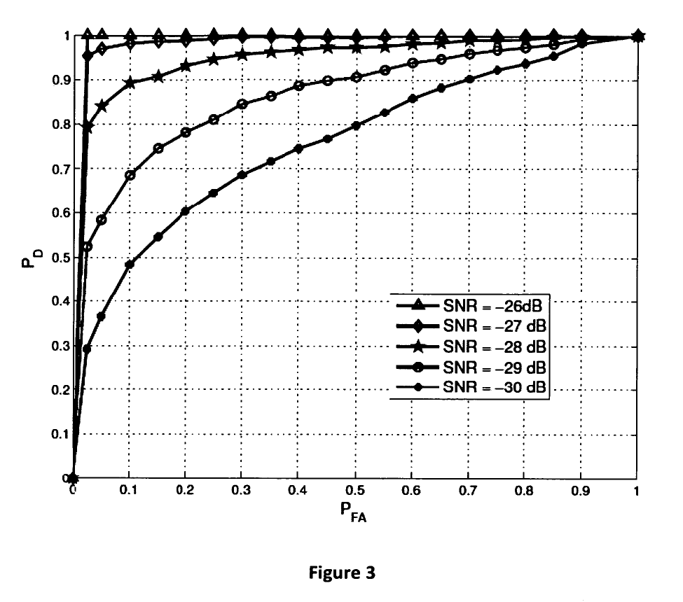

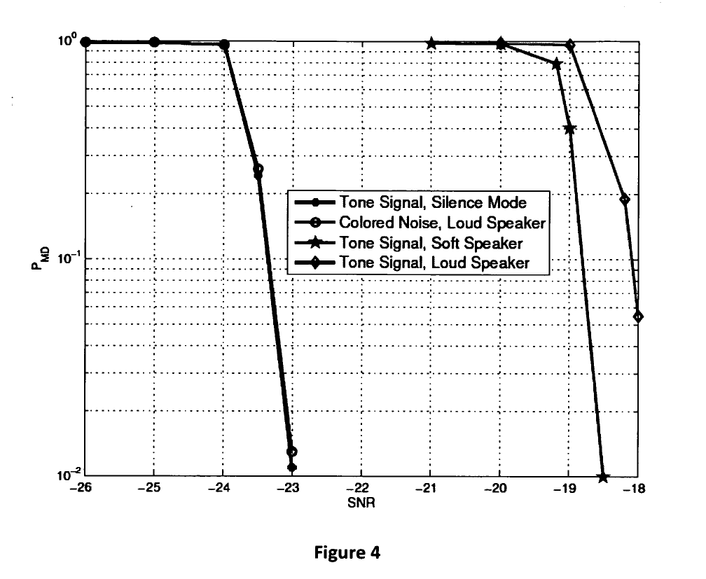

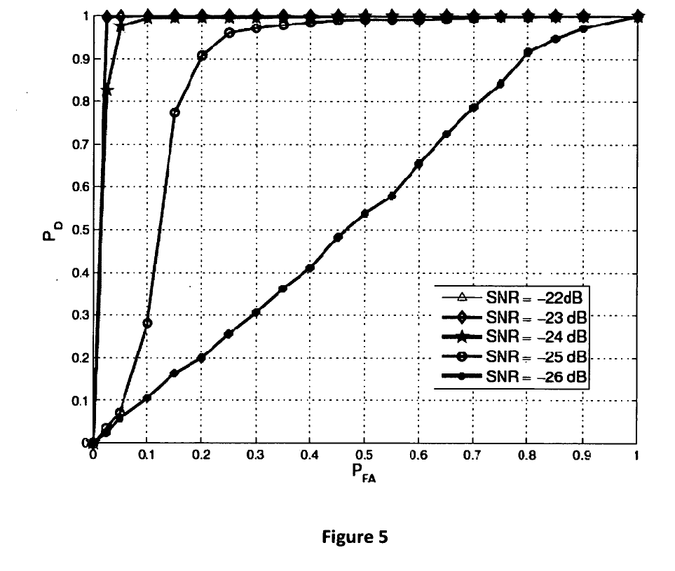

FIG. 2 shows the sensing performance of an autocorrelation detector specified in (7) and (8) for FM wireless microphone signals without interference and P_{FA}=0.5% with a sensing time of 5 ms (Nᵣ=107622). The curves in the figure show the probability of miss detection (P_{MD}), at corresponding SNR. The parameter M is equal to 100. The sensing performances are similar for four different voice sources. The required SNR to achieve P_{MD}<0.01 is −26 dB. It demonstrates that the autocorrelation detector specified in (8) has a very promising sensing ability for FM wireless microphone signals. The sensing performance degrades when the FM frequency deviation factor increases due to the accuracy of the approximation made in (3). FIG. 4 shows the sensing performance of a higher order statistic detector specified in (18) for FM wireless microphone signals with interference and P_{FA}=0.5% with a sensing time of 100 ms (Nᵣ=21524400). The parameters D, M and K are 200, 500, and 200. The sensing time is tremendously increased due to the need of averaging out interference. The required SNR to achieve P_{MD}<0.1 for all wireless microphone simulation models is −18 dB. A family of Receiver Operating Characteristic (ROC) curves at different levels of SNR is plotted in FIG. 3 (without interference) and FIG. 5 (with interference) to summarize the sensing performance of the proposed spectrum sensors. In these two figures, the simulation model using colored noise as a voice source is selected because it is closer to a voice signal than a tone signal. A reliable spectrum sensor should achieve high probability of detection (P_{D}) with respect to a low P_{FA}. From the ROC curves, the proposed FM wireless microphone spectrum sensor is reliable when SNR is −23 dB when a strong adjacent channel interference exists.

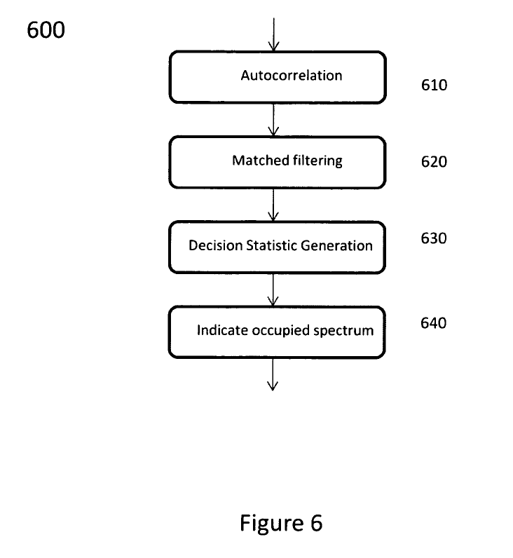

One embodiment of the present principles is illustrated in FIG. 6, which shows a first exemplary method 600. The method comprises performing an autocorrelation on a received signal in step 610, which may contain FM wireless microphone signals. The autocorrelation output is next filtered by a matched filter in step 620. The matched filter output is next used to determine a decision statistic in step 630. The decision statistic is used to indicate occupied spectrum in step 640.

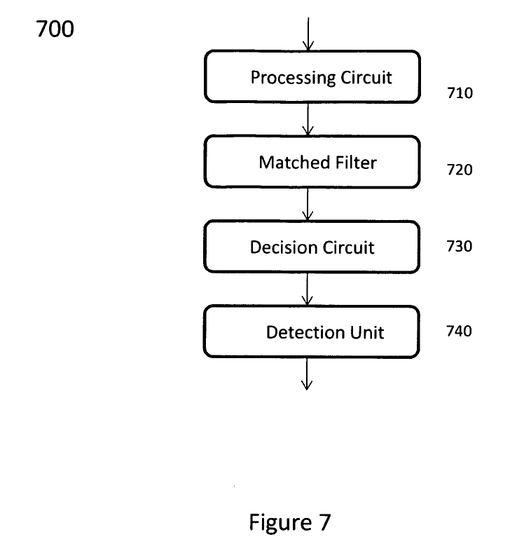

Another embodiment of the present principles is illustrated in FIG. 7, which shows a first exemplary apparatus 700. The apparatus comprises a processing circuit 710 for generating an autocorrelation function on a received signal. The output of the processing circuit is connected in signal communication with a matched filter 720 for filtering the autocorrelation output of the processing circuit 710. The output of the matched filter 720 is connected in signal communication with a decision circuit 730 for generating a decision statistic by finding the maximum value of the matched filter output 720. The decision circuit 730 output is connected in signal communication with a detection unit 740 to indicate occupied spectrum space by using the decision statistic.

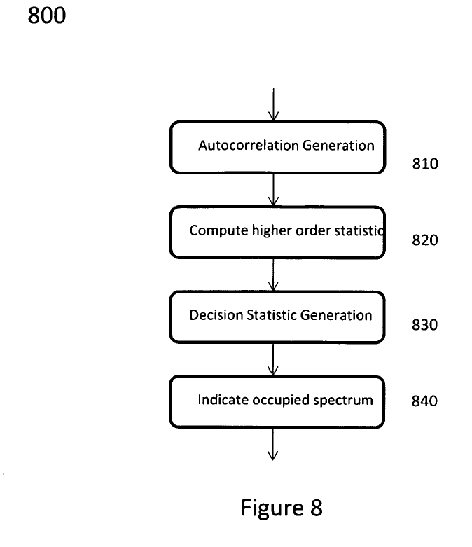

Another embodiment of the present principles is illustrated in FIG. 8, which shows a second exemplary method 800. The method comprises performing an autocorrelation on a received signal in step 810, which may contain FM wireless microphone signals. The autocorrelation output is next used to compute a higher order statistic in step 820. The output of step 820 is next used to determine a decision statistic in step 830. The decision statistic is used to indicate occupied spectrum in step 840.

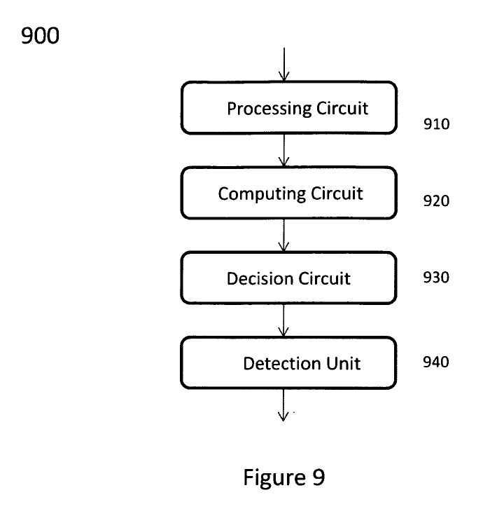

Another embodiment of the present principles is illustrated in FIG. 9, which shows a first exemplary apparatus 900. The apparatus comprises a processing circuit 910 for generating an autocorrelation function on a received signal. The processing circuit output is connected in signal communication with a computing circuit 920 for calculating a higher order statistic using the autocorrelation output of the processing circuit 910. The output of the computing circuit 920 is connected in signal communication with a decision circuit 930 for generating a decision statistic by finding the maximum value of the computing circuit output 920. The decision circuit 930 output is connected in signal communication with a detection unit 940 to indicate occupied spectrum space by using the decision statistic.

The functions of the various elements shown in the figures may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (“DSP”) hardware, read-only memory (“ROM”) for storing software, random access memory (“RAM”), and non-volatile storage.

Other hardware, conventional and/or custom, may also be included. Similarly, any switches shown in the figures are conceptual only. Their function may be carried out through the operation of program logic, through dedicated logic, through the interaction of program control and dedicated logic, or even manually, the particular technique being selectable by the implementer as more specifically understood from the context.

A description will now be given of the many attendant advantages and features of the present principles, some of which have been mentioned above. For example, a method for spectrum sensing of FM wireless microphone signals that performs an autocorrelation function, followed by matched filtering, and generating a decision statistic which is used to determine the presence of FM wireless microphone signals within a spectrum space. Another feature is approximating the autocorrelation function in the previous method with a function comprising a sinusoidal signal. Another advantage is an apparatus for performing spectrum sensing of FM wireless microphone signals comprising a processing circuit for generating an autocorrelation function, a matched filter, a decision circuit for generating a decision statistic, and a detection unit for using the decision statistic to indicate occupied spectrum space. Yet a further advantage is the apparatus just mentioned, wherein the autocorrelation function is approximated with a function comprising a sinusoidal signal. Another advantage of the present principles is a method for spectrum sensing of FM wireless microphone signals that performs an autocorrelation function, followed by forming a higher order statistic from the autocorrelation output, and generating a decision statistic by finding the maximum value of the higher order statistic, which is used to determine the presence of FM wireless microphone signals within a spectrum space. Yet another advantage of the present principles is the method just mentioned, but wherein the higher order statistic is formed by accumulating autocorrelation function products. Yet a further advantage of the present principles is the method just mentioned, but wherein the higher order statistic is approximated by a function comprising a sinusoidal signal. Another advantage of the present principles is an apparatus for spectrum sensing of FM wireless microphone signals comprising a processing circuit that performs an autocorrelation function in signal communication with a computing circuit for forming a higher order statistic from the autocorrelation output. The higher order statistic is input to a decision circuit for generating a decision statistic by finding the maximum value of the higher order statistic, which is used to determine the presence of FM wireless microphone signals within a spectrum space in a detection unit. A further advantage of the present principles is the apparatus just mentioned, wherein the computing circuit calculates the higher order statistic by accumulating autocorrelation function products. Yet another advantage of the present principles is the apparatus just mentioned, but wherein the computing circuit approximates the higher order statistic with a function comprising a sinusoidal signal.

The present description illustrates the present principles. It will thus be appreciated that those skilled in the art will be able to devise various arrangements that, although not explicitly described or shown herein, embody the present principles and are included within its spirit and scope.

All examples and conditional language recited herein are intended for pedagogical purposes to aid the reader in understanding the present principles and the concepts contributed by the inventor(s) to furthering the art, and are to be construed as being without limitation to such specifically recited examples and conditions.

Moreover, all statements herein reciting principles, aspects, and embodiments of the present principles, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Thus, for example, it will be appreciated by those skilled in the art that the block diagrams presented herein represent conceptual views of illustrative circuitry embodying the present principles. Similarly, it will be appreciated that any flow charts, flow diagrams, state transition diagrams, pseudocode, and the like represent various processes which may be substantially represented in computer readable media and so executed by a computer or processor, whether or not such computer or processor is explicitly shown.

In the claims hereof, any element expressed as a means for performing a specified function is intended to encompass any way of performing that function including, for example, a) a combination of circuit elements that performs that function or b) software in any form, including, therefore, firmware, microcode or the like, combined with appropriate circuitry for executing that software to perform the function. The present principles as defined by such claims reside in the fact that the functionalities provided by the various recited means are combined and brought together in the manner which the claims call for. It is thus regarded that any means that can provide those functionalities are equivalent to those shown herein.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment.

In conclusion, simulation results reveal that the proposed spectrum sensor becomes reliable when the SNR is −23 dB. The spectrum sensing algorithms presented can achieve the sensing threshold of SNR=−18 dB, as specified by the FCC, when a strong adjacent channel interference exists.

1. A method of spectrum sensing, comprising:
generating an autocorrelation function on a received signal;
filtering said autocorrelation output using a matched filter;
generating a decision statistic by finding the maximum value of the matched filter output; and
indicating occupied spectrum space by using said decision statistic.

2. The method of claim 1, wherein the autocorrelation function is approximated with a function comprising a sinusoidal signal.

3. An apparatus for spectrum sensing, comprising:
a processing circuit for generating an autocorrelation function on a received signal;
a matched filter for filtering said autocorrelation output;
a decision circuit for generating a decision statistic by finding the maximum value of the matched filter output; and
a detection unit for indicating occupied spectrum space using said decision statistic.

4. The appatus of claim 3, wherein the autocorrelation function is approximated with a function comprising a sinusoidal signal.

5. A method of spectrum sensing, comprising:
generating an autocorrelation function on a received signal;
computing a higher order statistic using said autocorrelation output;
generating a decision statistic by finding the maximum value of said higher order statistic; and
indicating occupied spectrum space by using said decision statistic.

6. The method of claim 5, wherein the higher order statistic is formed by accumulating autocorrelation function products.

7. The method of claim 5, wherein the higher order statistic is approximated by a function comprising a sinusoidal signal.

8. An apparatus for spectrum sensing, comprising:
a processing circuit for generating an autocorrelation function on a received signal;
a computing circuit for calculating a higher order statistic using said autocorrelation output;
a decision circuit for generating a decision statistic by finding the maximum value of said higher order statistic; and
a detection unit for indicating occupied spectrum space using said decision statistic.

9. The apparatus of claim 8, wherein the computing circuit calculates the higher order statistic by accumulating autocorrelation function products.

10. The apparatus of claim 8, wherein the computing circuit approximates the higher order statistic with a function comprising a sinusoidal signal.
